(19) United States
(12) Patent Application Publication
(10) Pub. No.: US 2015/0206750 A1
(43) Pub. Date: Jul. 23, 2015

(54) Method for Making Contact between a Semiconductor Material and a Contact Layer

(71) Applicant: Robert Bosch GmbH, Stuttgart (DE)

(72) Inventor: Thomas Suenner, Stuttgart (DE)

(73) Assignee: Robert Bosch GmbH, Stuttgart (DE)

(21) Appl. No.: 14/416,733

(22) PCT Filed: Jun. 4, 2013
(86) PCT No.: PCT/EP2013/061427

§ 371 Date: Jan. 23, 2015

(30) Foreign Application Priority Data
Jul. 25, 2012 (DE) 10 2012 213 077.2

(51) Int. Cl. H01L 21/04; H01L 21/321; H01L 21/285

(52) U.S. Cl. CPC H01L 21/0485; H01L 21/2855; H01L 21/28568; H01L 21/321

(57) ABSTRACT

A method for making contact between (i) a semiconductor material having silicon carbide and (ii) a contact layer having nickel oxide includes applying the contact layer to the semiconductor material, and treating at least an interface between the contact layer and the semiconductor material at an elevated temperature. An ohmic contact between the contact layer and the semiconductor material has an improved long-term stability due to an improved adhesion of the nickel to the silicon carbide. The present disclosure furthermore relates to a method for producing a semiconductor component, and to a semiconductor component.

The present invention relates to a method for making contact between a semiconductor material and a contact layer, the semiconductor material comprising silicon carbide. The present invention furthermore relates to a method for producing a semiconductor component, and to a semiconductor component.

### PRIOR ART

Contacts, for example ohmic contacts, are used in a multiplicity of applications, and are therefore widespread.

Application fields of ohmic contacts include, for example, semiconductor elements such as field-effect transistors. An ohmic contact may, for example, be formed from n-doped silicon carbide on which a contact, for instance comprising nickel, is applied. In particular, the use of nickel for n-doped silicon carbide can be advantageous because of the low contact resistivity.

With such contacts, there is the known risk that nickel reacts with the silicon from the semiconductor material or from the silicon carbide to form nickel silicide, in which case elemental carbon may be precipitated. The precipitated carbon may in this case cause reduced adhesion of further metal layers on the contact layer or of the contact layer, for instance the nickel layer, on the semiconductor material.

### DISCLOSURE OF THE INVENTION

The present invention relates to a method for making contact between a semiconductor material and a contact layer, the semiconductor material comprising silicon carbide (SiC), comprising the method steps of:

a) applying a contact layer onto the semiconductor material, the contact layer comprising nickel oxide (NiO) and optionally nickel (Ni); and

b) treating at least the interface between the contact layer and the semiconductor material with elevated temperature.

Contact-making in the sense of the present invention may, in particular, be understood as the application of a layer onto the semiconductor while forming direct physical contact. The corresponding applied layer may, in particular, be referred to as a contact layer.

In the sense of the present invention, treatment with elevated temperature may furthermore be understood, in particular, as a treatment which takes place at a temperature higher than room temperature.

For example, such a temperature may be several 100° C.

Furthermore, a treatment at least of the interface between the contact layer and the semiconductor material with elevated temperature may, in the sense of the present invention, mean in particular that at least the direct transition from the semiconductor material, i.e. the silicon carbide, to the applied layer, which may comprise essentially only nickel oxide or a mixture of nickel oxide and nickel, is treated with elevated temperature, i.e. an elevated temperature is applied at least to this region; this may include radiation into the corresponding layers. Thus, the temperature acts at least partially in the two neighboring layers. In this case, for example, only the interface per se may be treated with elevated temperature, or an elevated temperature acts only on this interface and optionally the neighboring environment, or an extended region of the contact layer or of the semiconductor, in which case the region may be dependent on the requirements of the product to be produced, for instance contact resistance or adhesion properties. For example, the entire arrangement consisting of semiconductor and contact layer applied thereon may be subjected to a heat treatment.

For the case of applying a mixture of nickel and nickel oxide in the contact layer, the method according to the invention may for example be used to produce an ohmic contact in which particularly good adhesion of the metal on the semiconductor can be possible. In this way, the reliability of such contacts, or their long-term stability, can be improved significantly. Furthermore, the contact resistance between the metal and the semiconductor may in this case not increase, or may increase only to a limited extent, so that the functionality of the ohmic contact thereby produced is not restricted, or is not restricted too greatly. The functionality of an ohmic contact, or of a component equipped with an ohmic contact produced in this way, can therefore remain substantially unaffected.

An ohmic contact may, in particular, be understood as an interface or transition between a metal and a semiconductor, this transition having in particular a low electrical resistance. Such an ohmic contact may behave as an ohmic resistance. It may, for example, be used to make contact with semiconductor-based electronic components, for example in order to connect them electrically to other components. In the present case, the ohmic contact may for example be made of silicon carbide, and nickel and nickel oxide.

In the case of using pure nickel oxide in the contact layer, it is furthermore likewise possible to produce a contact which, owing to particularly good adhesion, can have very high reliability, and may furthermore optionally have a particularly low contact resistance.

A method configured as described above can therefore particularly advantageously be used to produce a contact at least of a subregion of a semiconductor material with a contact layer.

Such a method comprises in a method step a) the application of a contact layer onto the semiconductor material, the contact layer comprising nickel oxide (NiO) and optionally nickel (Ni). It is therefore possible to apply essentially pure nickel oxide or a mixture of nickel and nickel oxide onto the semiconductor material. The contact layer, or the mixture of nickel and nickel oxide, may in this case essentially have any suitable mixing ratio. Furthermore, the nickel oxide or the mixture comprising nickel and nickel oxide may have further constituents, for instance silicon. In particular, further metals may be present, for example titanium (Ti), aluminum (Al) and/or cobalt (Co). Furthermore, the nickel oxide or the mixture of nickel and nickel oxide may be applied in various ways onto the semiconductor material, or onto a spatially limited subregion of the semiconductor material, as explained in detail below.

After method step a), the semiconductor material, i.e. the silicon carbide, is therefore in direct contact with the contact layer, i.e. with nickel oxide or a mixture of nickel and nickel oxide.

In a further method step b), at least the interface between the contact layer, i.e. the nickel oxide and optionally the nickel, and the semiconductor material is treated with elevated temperature. A treatment with elevated temperature can cause the nickel oxide, or parts of the nickel oxide, of the metal layer to react with silicon carbide to form nickel silicide. In this case, the oxygen present in the nickel oxide is furthermore released and the carbon present in the silicon carbide of the semiconductor may be precipitated as elemental carbon. The oxygen released can then react directly with the precipitated carbon and be released, or diffuse, from the solid material as carbon oxide, for instance carbon monoxide or carbon dioxide, as a gaseous substance.

Consequently, by the method described above, the carbon formed during production of the contact, for instance the ohmic contact, can be removed suitably from the solid material, so that no carbon occurs, or the carbon content is at least significantly reduced, particularly at the interface between the semiconductor material and the contact layer, i.e. for instance on the ohmic contact per se. By at least reducing the carbon content, or by fully removing the carbon content, from the interface or the transition from semiconductor material to the applied contact layer, the adhesion of the layer on the semiconductor can therefore be improved significantly.

In this case, depending on the method carried out, the carbon may be removed only on the lower interface of the applied layer comprising nickel oxide and optionally nickel, i.e. on the transition surface to the semiconductor, or in further regions of the contact layer, so that further application of another metal or another metal layer onto the contact layer can also be improved. This may, for instance, be achievable in particular through the proportion of nickel oxide introduced and its penetration in the applied contact layer. This may, for instance, be advantageous since, depending on the reaction conditions, carbon may form not only on the direct interface, but carbon may furthermore also occur inside the contact layer, or on the contact layer surface arranged facing the semiconductor. For example, the carbon may be present together with the silicon carbide. Therefore, particularly in the case of a multilayer structure, penetration of the nickel by nickel oxide before the heat treatment may be advantageous so that a multilayer structure can also be produced particularly stably and reliably.

Since by the use of nickel oxide in the formation of an ohmic contact, for example, an increased resistance, or contact resistance, of the transition from semiconductor to the metal may be possible, the amount of nickel oxide used can advantageously be adapted as accurately as possible to the requirements of the respective application. For example, the amount of nickel oxide used, or applied, may be tailored to the requirements of, for instance, minimum adhesion or maximum electrical resistance. In other words, the introduction of nickel oxide can be limited to an amount such that, in the ohmic contact produced in the metal layer, i.e. in particular the nickel layer, there is sufficient adhesion but the resistance can only be increased to such an extent that the functionality is still readily possible. For example only so much nickel oxide may be introduced, or be present before the heat treatment, as is converted essentially fully after a heat treatment and therefore a reaction of the oxygen present in the nickel oxide with the released carbon, and the ohmic contact produced therefore essentially only comprises silicon carbide and metallic nickel. In this case, there is no increase in the contact resistance, but the adhesion can furthermore be improved significantly by reducing the carbon content.

Contrary to the production methods known from the prior art for ohmic contacts, for example, in which oxidation of the nickel is specifically intended to be prevented, controlled and defined provision of nickel oxide in the method described above precisely leads to an improvement in the adhesion of the metal layer onto the semiconductor and thus allows improved properties, in particular an improved long-term stability.

This may, for example, be demonstrated by the adhesion of an aluminum metallization on the finished contact increasing by more than a factor of 1.5. This was determined by tests with aluminum bonds that were applied onto silicon oxide regions and onto nickel contact regions. Both had the corresponding adhesion.

In the scope of one configuration, in method step a) the application of a contact layer onto the semiconductor material may be carried out by sputtering nickel oxide and optionally nickel. In this configuration, application e.g. of a mixture of nickel and nickel oxide onto the semiconductor material, or onto at least one defined subregion of the semiconductor material, can therefore be applied in just one method step, which can therefore make the method in this configuration particularly simple and economical. Furthermore, in particular this configuration the amount of nickel oxide and optionally nickel, or for example the penetration of the metal layer with nickel oxide, can be controllable in a particularly defined way, so that the product obtainable can also be particularly defined.

Furthermore, between the semiconductor and the contact layer, particularly in the case of application by sputtering, there is an interface which may have a particularly low contact resistance. In this way, the contact, for example the ohmic contact, can have a particularly low contact resistance in this configuration, which makes it particularly suitable for use in a multiplicity of applications.

In this case, a sputtering process may be advantageous particularly for common application of nickel and nickel oxide, in order to obtain a mixture of nickel and nickel oxide, onto the semiconductor material, or the silicon carbide. Sputtering is a physical process, known per se, in which atoms are removed from a solid body, which in this case may in particular comprise nickel or nickel oxide, or consist thereof, in particular by the action of high-energy ions, for example noble gas ions, and these atoms enter the gas phase and can be deposited on the semiconductor material. Suitable method parameters for sputtering to apply a mixture of nickel oxide and optionally nickel onto a silicon carbide surface include, by way of example us without restriction, an input power of 1000 W in DC voltage with sputtering pressures of 2 10² mbar.

In the scope of another configuration, in method step a) a mixture of nickel and nickel oxide may be applied onto the semiconductor material by the method steps of:

a1) applying a layer comprising nickel onto the semiconductor material; and

a2) at least partially oxidizing the nickel applied in method step a1).

In this configuration, therefore, in a first method step 1) a layer of, in particular, essentially pure nickel is applied onto the semiconductor material, or onto a defined subregion of the semiconductor material. This reaction step, or the application only of, in particular, pure nickel onto the semiconductor material, or onto the silicon carbide, is for example known per se from the production of conventional ohmic contacts.

In a further method step a2), in this configuration the nickel layer applied in method step a1) may subsequently be at least partially oxidized, or at least a part of the applied nickel may be oxidized. In this way, by defined oxidation of the nickel applied in method step a1), a defined amount of nickel oxide can be produced. In detail, an amount of nickel may be oxidized to nickel oxide such as, for example, can fully react by reaction of the oxygen with the released carbon as described above in a subsequent temperature step, or a subsequent heat treatment. In this configuration, it is therefore possible to use a production process known per se for an ohmic contact, which is modified in such a way that nickel can be oxidized in an intermediate reaction. In this way, devices used in known processes can essentially be employed, which makes the method particularly simple. In this configuration, therefore, oxidation of the nickel is not prevented as is usual in the prior art, but specifically ensures improved properties of the ohmic contact produced, for example.

In the scope of another configuration, in method step a1) the application of a layer comprising nickel onto the semiconductor material may be carried out by sputtering or vapor deposition. By sputtering, nickel can be applied in a particularly defined way, and simply and economically. Furthermore, between the semiconductor and the metal, i.e. between the silicon carbide and the nickel, particularly in the case of applying nickel by sputtering, there is an interface which, for instance, has a particularly low contact resistance after heat treatment. In this configuration, the ohmic contact can therefore have a low contact resistance, which makes it particularly suitable for use for a multiplicity of applications. Furthermore, possible positive examples of the application of pure nickel include for instance vapor deposition, for example electron beam deposition or laser beam deposition.

A very defined layer of the nickel can likewise be applied by vapor deposition, so that a contact with defined properties, and in particular a low contact resistance, can be producible.

In the scope of another configuration, method step a2) may be carried out by plasma treatment, wet chemical oxidation, or by storing the nickel applied in method step a1) under oxidizing conditions.

In this configuration, the nickel applied in method step a1) is therefore at least partially oxidized, for instance by the effect of an oxidizing plasma, for example an oxygen plasma. The adhesion of individual layers to one another can in this case be improved even further by the effect of a plasma. Furthermore, through the use of a plasma, oxidation of the nickel can take place in a particularly defined way. It is therefore possible to produce layers which have a particularly defined proportion, or particularly defined penetration, of nickel oxide. Furthermore, plasma-based oxidation can be carried out simply and economically, so that the overall method can be carried out particularly economically and simply in this configuration. Suitable reaction parameters for oxidizing the nickel arranged on the semiconductor substrate in a particularly defined way are, for instance, an 800 W plasma in oxygen with 600 sccm (standard cubic centimeters per minute) of oxygen. An oxygen plasma may in particular be used in this case. Other alternatives of a plasma which may be used include for example, a mixture of oxygen with other gases, such as argon (Ar) or nitrogen (N₂).

With respect to wet chemical oxidation or storage under oxidizing conditions, very defined oxidation can likewise be carried out, and such methods can furthermore be applied particularly simply and economically.

In the scope of another configuration, in method step a2) nickel may be oxidized in a proportion of from more than 0 at % (atomic per cent) to less than or equal to 100 at %. In this configuration, the amount of nickel oxide introduced can be kept particularly small, so that oxidation can be possible under mild conditions and for short periods of time, so that the method can be carried out particularly economically in this configuration.

In the scope of another configuration, in method step a) nickel oxide may be applied onto the semiconductor material with a thickness in a range of less than or equal to 1 μm, for example with a thickness in a range of 30 nm. In this configuration, the nickel oxide is therefore always in immediate proximity to the semiconductor material, so that the formation of the nickel oxide can essentially cause only contact between the semiconductor material and the metal, i.e. the silicon carbide and the nickel, by removal of carbon, as described above. Penetration of the nickel with nickel oxide over its entire thickness is not necessary in this case, and does not take place, which can improve the conductivity of the contact produced, or of the nickel layer. In this way, the nickel oxide introduced can be reduced to a minimum amount, and furthermore the adhesion of the nickel on the silicon carbide can be improved without restrictions, and in particular in the best possible way.

This configuration may, for example, be performable by carrying out simultaneous application of nickel and nickel oxide by sputtering only until the aforementioned thickness is reached. Following this, deposition only of nickel takes place. As an alternative, a plasma may be used in such a way that it only affects the thickness of the nickel, as described above.

The thickness of the nickel oxide may therefore refer, for example, to the thickness of a pure nickel oxide layer, to the thickness of a mixture of nickel and nickel oxide, or to the thickness of the presence of nickel oxide in a mixture of nickel and nickel oxide.

In the scope of another configuration, in method step b) at least the interface between the contact layer and the semiconductor material may be heated to a temperature in a range of from greater than or equal to 600° C. to less than or equal to 1500° C., particularly in a range of from greater than or equal to 850° C. to less than or equal to 1050° C. The existence of such a temperature can ensure that a reaction of the nickel oxide with the silicon carbide, with expulsion of the carbon as a gaseous compound, can take place particularly reliably and fully. Furthermore, in this configuration it is possible to select a temperature which does not place great requirements on the heating element, and furthermore does not damage the materials used.

Furthermore, in this configuration, for example, a heat treatment may be carried out for a time of from greater than or equal to 0.5 min to less than or equal to 5 min, for example for 2 min.

With respect to other features and advantages of the method according to the invention for making contact between a semiconductor material and a contact layer, reference is hereby made explicitly to the explanations in connection with the method according to the invention for producing a semiconductor component, as well as to the semiconductor component.

The present invention furthermore relates to a method for producing a semiconductor component, comprising a method configured as described above for making contact between a semiconductor material and a contact layer. Such a method for producing a semiconductor component can therefore be used, in particular, to produce a semiconductor component which has a particularly long-term stable ohmic contact, for example, i.e. an interface between metal and semiconductor component. Such semiconductor components include, for example, power semiconductors such as MOS transistors and trench MOS transistors.

Such a method for producing a semiconductor component offers the advantage that the metallic contact can adhere particularly well on the semiconductor material, so that the semiconductor component can be particularly long-term stable even under harsh conditions, and can therefore operate particularly reliably. In this case, the contact resistance of the ohmic contact of the semiconductor component, for example, is not increased or is increased only slightly, so that a semiconductor component produced as described above can operate without great restrictions. Consequently, a method as described above is highly suitable for a multiplicity of semiconductor components, on which great requirements may also be placed in respect of their mode of operation.

With respect to other features and advantages of the method according to the invention for producing a semiconductor component, reference is hereby made explicitly to the explanations in connection with the method according to the invention for making contact between a semiconductor material and a contact layer, as well as to the semiconductor component.

The present invention furthermore relates to a semiconductor component produced by a method configured as described above for producing a semiconductor component. Such a semiconductor component offers the advantage that it operates particularly reliably and long-term stably owing to improved adhesion of a metal contact, in particular a nickel contact, on the semiconductor.

Improved adhesion may in this case be obtained, in particular, in that there can be a significantly reduced carbon content at the ohmic contact of the semiconductor component, for example, i.e. in particular at the interface between the contact layer and further metallizations. Such a carbon content, or content of elemental carbon, on the contact, or on the surface of the contact layer, results in significantly less than 100% coverage, typically 1% coverage, of the contact, or of the contact layer, by carbon.

Examples of such semiconductor components include, for example, power semiconductors such as MOS transistors and trenchMOS transistors.

With respect to other features and advantages of the semiconductor component according to the invention, reference is hereby made explicitly to the explanations in connection with the method according to the invention for making contact between a semiconductor material and a contact layer, as well as to the method for producing a semiconductor component.

1. A method of producing a contact between a semiconductor material and a contact layer, comprising:
a) applying a contact layer having nickel oxide onto a semiconductor material having silicon carbide; and
b) treating at least an interface between the contact layer and the semiconductor material with an elevated temperature.

2. The method as claimed in claim 1, wherein the application of the contact layer onto the semiconductor material includes sputtering nickel oxide.

3. The method as claimed in claim 1, wherein the application of the contact layer onto the semiconductor material includes applying a mixture of nickel and nickel oxide onto the semiconductor material via:
a1) applying a layer having nickel onto the semiconductor material; and
a2) at least partially oxidizing the layer having nickel.

4. The method as claimed in claim 3, wherein the application of a layer having nickel onto the semiconductor material includes sputtering or vapor deposition.

5. The method as claimed in claim 3, wherein the at least partial oxidation of the layer having nickel includes plasma treatment, wet chemical oxidation, or storing the nickel under oxidizing conditions.

6. The method as claimed in claim 3, wherein the at least partial oxidation of the layer having nickel includes oxidizing the nickel in a proportion of from more than 0 at % to less than or equal to 100 at %.

7. The method as claimed in claim 1, wherein the application of the contact layer onto the semiconductor material includes applying nickel oxide onto the semiconductor material with a thickness in a range of less than or equal to 1 μm.

8. The method as claimed in claim 1, wherein the treatment of the interface includes heating at least the interface between the contact layer and the semiconductor material to a temperature in a range of from greater than or equal to 600° C. to less than or equal to 1500° C.

9. A method for producing a semiconductor component, comprising:
producing a contact between a semiconductor material having silicon carbide and a contact layer having nickel oxide, via:
applying a contact layer onto the semiconductor material; and
treating at least an interface between the contact layer and the semiconductor material with an elevated temperature.

10. A semiconductor component produced by a method as claimed in claim 9.

11. The method of claim 1, wherein the contact layer further includes nickel.

12. The method of claim 2, wherein the application of the contact layer onto the semiconductor material further includes sputtering nickel.
